(19) United States
(12) Patent Application Publication
(10) Pub. No.: US 2008/0251812 A1
(43) Pub. Date: Oct. 16, 2008

(54) Heteroepitaxial Crystal Quality Improvement

(76) Inventor: Woo Sik Yoo, Palo Alto, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/735,848

(22) Filed: Apr. 16, 2007

(51) Int. Cl. H01L 29/06; H01L 21/20

(52) U.S. Cl. 257/183; 438/492; 257/E21.09; 257/E29.005

(57) ABSTRACT

Methods and systems for improving heteroepitaxial crystal quality of semiconductor materials include forming a pattern on the semiconductor substrate over which the hetero-epitaxial layer is grown. The pattern provides predetermined sites for dislocation initiation and termination of dislocation propagation. The layer may be treated with a focused laser beam during or subsequent to the layer growth process. Laser light may be focused at a selected depth, where the light intensity is sufficient to cause structural and/or electronic changes localized at that depth. The laser beam may be selectively scanned to provide the desired change only at preferred spatial locations on the substrate. The laser wavelength and power may be selected to be appropriate for the materials being treated.

### BACKGROUND

1. Field of Invention

This disclosure generally relates to method of improving heteroepitaxial crystal quality in semiconductor fabrication processes.

2. Related Art

An epitaxial film is a layer of crystalline material grown over the atomic sites of a crystalline substrate that is of identical material or has nearly identical interatomic spacing—i.e., lattice constants. Because the materials are either identical or nearly so, such techniques may be used to grow films of quality superior to the substrate material, or to include dopants to alter the electronic or optical characteristics of the surface layer.

Heteroepitaxy refers to a specialized thin-film technique of deposition in which different materials are involved. It is used for the growth of semiconductor crystals of one material with characteristic atomic lattice dimensions on the crystal face of another material having different atomic lattice dimensions. A thin-film whose material lattice orientation is the same as that of the substrate on which it is deposited usually results. The thin-film will be nominally a single crystal if the substrate happens to be a single crystal. The technique of heteroepitaxy is applied to growing crystalline films of materials of which individual crystals cannot be obtained. Integrated crystalline structures of different layers, used in semiconductor technology are fabricated using heteroepitaxy.

The technique of heteroepitaxy is widely used in the manufacture of semiconductor and photonic devices. Nanotechnology also requires the use of such a technique. Heteroepitaxy is a method of growing high crystalline quality structures for semiconductor materials like gallium arsenide and indium phosphide, which are used in a wide variety of electrical engineering applications. Various combinations of heteroepitaxial crystalline layers grown on lattice mismatched substrates are known in the art.

It is typical of the grown layer of material to have lattice dimensions in the pure crystaline state that are not identical to that of the substrate material upon which it is grown. The energetics of growing the film essentially one atomic layer at a time builds up a stress potential energy due to the interatomic squeezing or stretching that occurs. Eventually, as the film becomes thick enough, the accumulated energy is sufficient to activate a slip between layers to release the stress. Therefore, in the first few layers, some misalignment of atoms may occur, which results in misfit dislocations site defects. Eventually, as the growth increases the heteroepitaxial layer thickness, the regularity and crystallographic property of the heteroepitaxial layer becomes more characteristic of the bulk equivalent of the newly grown compound semiconductor material. However, defects may propagate into the grown heteroepitaxial layer as a result of the stress relief process described above.

Dislocations and other defects in the grown crystal lattice structure may develop. Examples are misfit and threading dislocations. Impurities may further contribute to dislocations. These dislocations may result in device performance that is inferior to that which may be obtained with dislocation free material. Defects in the heteroepitaxial layer have a negative impact on electrical properties of semiconductor materials. Electronic mobility in semiconductors may be adversely affected by such defects. For example, diode junctions may tend to be undesirably leaky, or may short altogether. Reducing defect density in the layer will improve device electrical performance. In addition, in optoelectronic applications, propagation attenuation of guided light waves increases if the defect density is significant. Thus, it is important to prevent dislocations from propagating far into the layer in order not to degrade the electronic and/or optical properties of the grown material. Therefore, it is desirable to have methods to trap, “fence in,” limit, and reduce such defects in order to improve the quality of the heteroepitaxial layer.

### SUMMARY

Methods of improving heteroepitaxially grown semiconductor materials and devices are disclosed. Specifically, in accordance with an embodiment of the disclosure, a method of scribing the surface of a substrate prior to heteroepitaxial growth is disclosed.

In accordance with an embodiment of the disclosure, selective depth laser processing to improve the crystalline quality of the hetero-epitaxial layer, which may be used singularly or in combination with scribing methods, is disclosed. Laser processing may be used to scribe patterns on the substrate, and may also be used to anneal or otherwise process layers grown on the substrate. Laser processing may comprise laser induced deposition, surface layer regrowth, surface and subsurface annealing.

In particular, a method includes preparing a semiconductor substrate surface in a prescribed pattern to produce various column, row or lattice patterns to provide growth sites for heteroepitaxial materials. The substrate may include a porous surface or be made rough by various preparations. The surface preparation (priming) may be achieved by various methods, including scribing (e.g., laser, mechanical, etc.), etching (e.g., gaseous, vapor, plasma, wet chemical, etc.), and may include photolithographic steps. The layer growth methods may be any of atomic layer epitaxy (ALE), atomic layer deposition (ALD), molecular beam epitaxy (MBE), chemical beam epitaxy (CBD), chemical beam epitaxy deposition (CBD), sputtering, magnetron sputtering, plasma reaction deposition, thermal evaporation, electron-beam evaporation, electro-plating, liquid phase epitaxy (LPE), molecular beam epitaxy (MBE) (e.g., metal-organic), chemical vapor deposition (CVD), and solid phase epitaxy (SPE) and related combinations of these processes.

Post-growth processing may include annealing, re-growth, activation, strain relief, etc., using thermal, laser, voltaic processes, etc., to effect changes in atomic mobility, lattice relaxation, minority carrier relaxation, etc. Specifically, selective depth focused laser treatment to initiate nucleation at selective depths and to limit dislocation propagation is disclosed.

A method of processing heteroepitaxial semiconductor materials includes providing a light beam of a selected wavelength and a selected peak power, focused at a selected depth to initiate processes affecting crystallographic and electronic properties of the heteroepitaxial layer at the selected depth. The laser beam may be continuous or modulated to provide pulses of a discrete time pulse width. The laser beam is focused at a depth below the surface of the semiconductor material to provide energy density sufficient to perform the desired process at the selected depth. The total energy in each laser pulse is controlled to a selected value. By controlling parameters of the light or laser beam, process effects may be limited to the selected depths. Device fabrication requiring heteroepitaxial layers is thereby improved by altering material electronic and/or optical properties and features below the surface of the semiconductor material.

### BRIEF DESCRIPTION OF THE DRAWINGS

FIG. 1A illustrates a variety of possible etch and scribe patterns, in accordance with an embodiment of the disclosure.

FIG. 1B shows several photographs of periodic and quasi-random patterns on Si wafers produced by laser melting or ablation of Si.

FIG. 2 is an illustration of a cross-section of an improved crystal quality hetero-epitaxially grown layer on a scribed or etched substrate in accordance with an embodiment of the disclosure.

FIG. 3 is a transmission electron microscope photograph of a SiC hetero-epitaxial layer grown on Si.

FIG. 4A is an illustration of a laser beam focused at an interface at a selected depth below the substrate surface, in accordance with an embodiment of the disclosure.

FIG. 4B illustrates the change in laser beam intensity with depth of the laser beam of FIG. 4A, in accordance with an embodiment of the disclosure.

Like reference symbols in the various drawings indicate like elements.

### DETAILED DESCRIPTION

Improvement of the interface quality to reduce propagation of defects is critical. For some devices, such as multiple quantum well solar cells, misfit dislocations, which occur to relieve strain in layers, typically have an adverse effect on minority carrier recombination. A method of controlling the growth and propagation of dislocations is desirable.

The principal property that governs generation of defects in heteroepitaxially grown layers is lattice mismatch. As a layer of material is grown on a substrate which has different interatomic dimensions, strain develops which distorts the crystalline structure of the layer from that of the pure single crystal form. The stress-strain relation created by displacement of atoms from their natural structure (by virtue of being grown on a foreign substrate of different interatomic dimensions) creates a buildup of potential energy, which increases as the layer grows thicker. If the thickness of the epitaxial layer is kept small enough to maintain the elastic strain energy below the energy of dislocation formation, the strained-layer structure will be thermodynamically stable against dislocation formation. The unstrained state of the lattice-mismatched layer is energetically most favorable, but the strained structure is stable against transformation to the unstrained state by the energy barrier associated with the generation of enough dislocations to relieve the strain. Eventually this stored energy exceeds the barrier, and strain is relieved by generation of dislocations.

Various forms of surface patterning and post processing have been suggested as methods for reducing the defect density in heteroepitaxial films, i.e., “fencing in,” or limiting defect propagation. The motivation for this method may be related to the controlled nucleation of defects and control of the induced “slip” provided in such structures to reduce stress and permit growth of higher quality layers. For example, photolithographic definition of a large lattice pattern on the substrate, followed by etching to define a recess structure with walls, heteroepitaxial growth of a different material, followed by annealing, has been shown to reduce threading dislocations in the heteroepitaxial film. The dimension period of the lattice-like pattern may depend on crystal structure and surface orientation, and more particularly on mismatch in the crystal lattice dimensions of the substrate and heteroepitaxial layer. For example, a large mismatch may require the surface pattern to have a smaller dimension in order to limit defect propagation, since internal stress may typically be greater.

Randomly scribed patterns or porous substrates may enhance defect density reduction through intentional defect path collisions along the growth directions. Substrates with a crystallographic axis a few degrees off the surface normal may also aid in controlling defect nucleation and growth, texture, epi-layer crystallinity, strain and defect density. The slope of etched or scribed structures formed on such surfaces may have a significant qualitative impact, particularly in controlling the directions in which defects can propagate, and therefore, how they may be trapped from growing. Therefore, by intentionally introducing damage nucleation sites near the growth interface, it may be possible to control defect generation density in the initial growth stage and influence the resulting crystalline quality of the hetero-epitaxial layer.

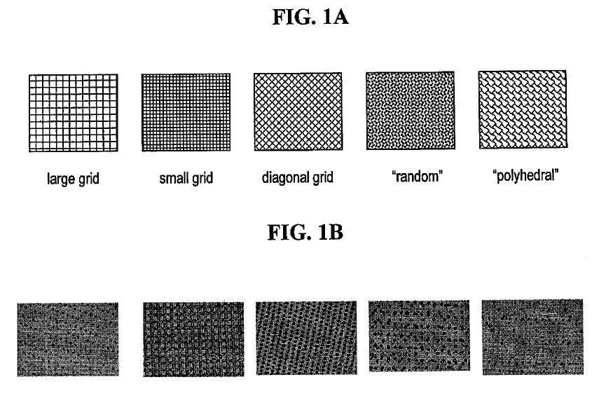

FIG. 1A illustrates a variety of possible etch and scribe patterns, in accordance with an embodiment of the disclosure. The patterns shown are exemplary and not limiting. Pattern generation parameters may include period dimension (i.e., spatial density), depth, shape, orientation, randomness, profile slope, alignment with crystal axis, etc. The dimensions and appearance of pattern features may depend on the crystal structure of both the base substrate, the crystallographic orientation of the exposed substrate surface, the crystal structure of the heteroepitaxial layer (particularly the lattice mismatch to the substrate), and the orientation of the profile slope with respect to major crystallographic axes. For example, if the lattice mismatch is small, less interfacial stress is expected, therefore, a larger pattern may be acceptable since dislocation growth may remain dimensionally small. Conversely, if there is a larger mismatch, the pattern may be made smaller to limit defect propagation, in effect pinning the lattice of the formed layer to a localized area. Where the lattice mismatch between the substrate and the heteroepitaxial layer is small, there is relatively little interfacial stress, so that the pattern may be larger. There is no hard boundary that defines small or large mismatch, but 1-2% may be considered small, whereas 3% or more may be considered relatively large, resulting in larger dislocations when the strain energy of the formed layer is large enough to cause the lattice to slip or shift, releasing the stored energy.

If the substrate surface orientation of a cubic crystal is <100> a square pattern may be preferred, whereas if the orientation is <111> a hexagonal pattern may be preferred. Ordering the shape and orientation of the pattern along crystallographic axes may promote more orderly growth of the heteroepitaxial layer. Conversely, a random etch pattern serve to trap the propagation of dislocations.

FIG. 1B shows microphotographs of examples of patterns produced on Si using a laser by means of melting and/or ablation. By proper selection of laser characteristics, i.e., wavelength, peak power, pulse width, scan rate and pattern, etc., a desired pattern can be produced.

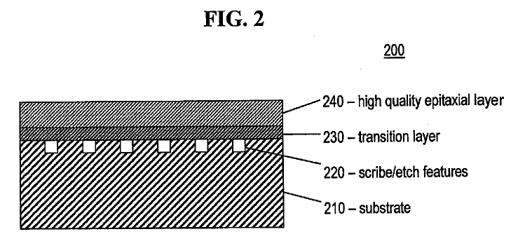

FIG. 2 is an illustration of a cross-section of a semiconductor structure 200 in which the substrate is scribed or etched in accordance with an embodiment of the disclosure. Beginning with a substrate 210 of a host material, a selected pattern 220 is scribed, etched, or otherwise formed. Patterns can be one of those shown in FIGS. 1A and 1B or any other suitable pattern. Pattern 220 functions to provide defect gettering (i.e., to minimize, or limit propagation of defects), stress relief, and sites for termination of dislocation propagation. The method of pattern generation may include laser marking, lithography, etching, mechanical scribing, scratching or ruling, or selected growth. Growth conditions may include promotion of a rough porous surface. Substrate 210 may comprise Si, SiC, sapphire, GaAs, InAs, related III-V and IV-IV or other highly crystalline materials that are commercially available. A variety of hetero-epitaxial layer/substrate combinations may be selected, which may include SiC/Si, GaAs/Si, GaN/Si, GaN/SiC, GaN/sapphire, and the like.

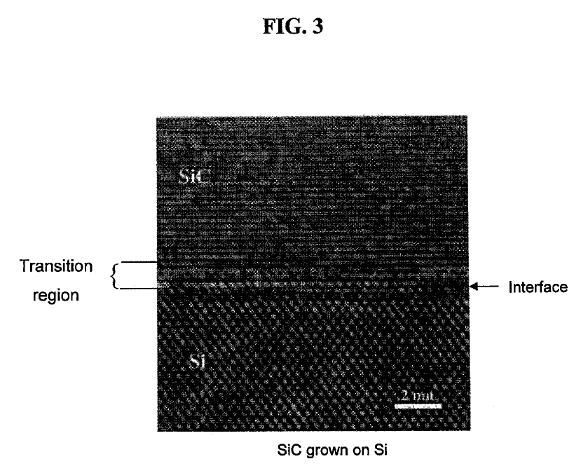

Once a pattern has been scribed or etched into substrate 210, a transition layer 230 is deposited over substrate 210. Depending on the degree of lattice mismatch, the transition layer may only be a few atomic layers thick (see FIG. 3, where, for example, SiC is shown grown on Si, with a transition layer of 5-6 atomic layers. Methods of layer growth are numerous, and may include, for example, atomic layer epitaxy (ALE), atomic layer deposition (ALD), molecular beam epitaxy (MBE), chemical beam epitaxy (CBD), chemical beam epitaxy deposition (CBD), sputtering, magnetron sputtering, plasma reaction deposition, thermal evaporation, electron-beam evaporation, electro-plating, liquid phase epitaxy (LPE), molecular beam epitaxy (MBE) (e.g., metal-organic), chemical vapor deposition (CVD), and solid phase epitaxy (SPE) and related combinations of these processes.

Transition layer 230 comprises the first several molecular layers of the compound semiconductor heteroepitaxial film being newly grown. Because the crystallography and interatomic dimensions—i.e., lattice constants—may differ from that of the substrate (e.g., the interatomic spacing in silicon may be expected to differ from that of SiC), there will be some gaps or crowding between atoms as they are deposited on the underlying substrate lattice.

An epitaxial layer 240 is then formed over transition layer 230. Because of pattern 220 scribed or etched into substrate 210, the resulting epitaxial layer 240 is a higher quality than a same or similar deposition without the patterned substrate. This may be so because the etched or scribed pattern 220 limits the propagation of dislocations on the order of the pattern size or less. As discussed above, a random (i.e., rough) etch pattern 220 may serve to trap the propagation of dislocations to dimensions corresponding to the order of the roughness. Typically, deposition processes start by producing “islands” of single crystals on the exposed single crystal surface of the substrate. Etch patterns 220 serve both as orderly epitaxial growth sites for the layer 240 and as traps to “pin” dislocation propagation.

FIG. 3 is a transmission electron microscope photograph of a SiC heteroepitaxial layer grown on Si, which illustrates the nature of the heteroepitaxial layer growth process. The interface between the Si substrate and the SiC layer grown on it is clearly visible by the change in crystalline morphology. A transition region is noted which is indicative of the change in crystallographic lattice constants that must be accommodated in going from one material to the other. This is the region in which stress arises as the interatomic distance is forced to change (i.e., is strained) as the species and stoichiometry changes from one atomic layer to the next from that of the substrate to that of the layer. It is in this region where dislocations generate.

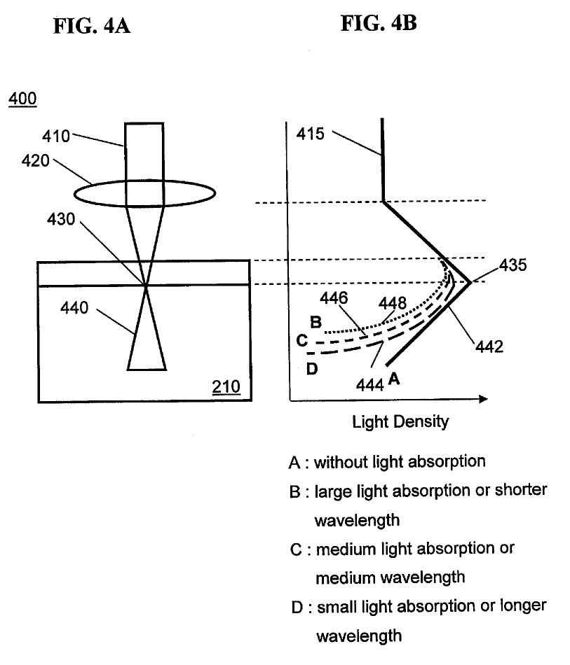

FIGS. 4A and 4B illustrate one example of how the scribing or etching can be performed on a substrate prior to epitaxial growth. Referring to FIG. 4A, a collimated light beam 410 is focused by a lens 420 at a selected depth 430 below the surface of a substrate 460, which may typically include transition layer 230. The beam density reaches substantially maximum value at this depth, where the intensity is sufficient to drive a process that alters the structural and/or electronic properties of the material within the immediate location of the focal point. The beam becomes a divergent beam 440 beyond this point, and the beam density correspondingly decreases, with correspondingly less energy density than would be sufficient to excite a structural or electronic alteration process in the material.

In FIG. 4B, the light density of the beam is shown as a function of its location in relation to the lens and substrate. As seen in this example, the collimated beam 410 has a constant aperture and light density 415 up to lens 420. Lens 420 may be representative of a single lens or a system of lenses. Lens 420 focuses the beam at selected depth 430 of substrate 460, and the corresponding light density reaches a maximum density 435 at selected depth 430. By positioning the selected depth to coincide substantially with transition layer 230, laser induced processes may be restricted to occur at a limited and specified depth. Those of ordinary skill in the art will further appreciate that by changing the details of lens 420, for example, by making the focal length shorter, the extent of the region of maximum density 435 will be both smaller in the direction of propagation, since the beam converges more quickly, and then diverges more quickly away from the region of maximum density (i.e., is tightly focused), but also that the beam intensity will be higher, since it follows from principals of optics that the diffraction limited spot size will then be smaller. Therefore, a shorter focal length may result in greater beam intensity—and therefore a more efficient process effect—over a more limited depth. This may be used to advantage to limit the extent of depth at which processing takes place, and to reduce the processing time. Additional details can be found in commonly-owned U.S. patent application Ser. No. 11/679,633, entitled “Selective Depth Optical Processing” and filed Feb. 27, 2007, which is incorporated by reference in its entirety.

Thus, such a laser beam 410 may also be used to perform the scribing and patterning process prior to layer growth. For example, laser beam 410 may be focused substantially at the surface of substrate 210. The beam density of the focused spot is sufficient to melt or ablate substrate material. Laser beam 410 is selected for wavelength, power and, if required, modulated to appropriately perform the scribing process.

Also, only those claims which use the word “means” are intended to be interpreted under 35 USC 112, sixth paragraph. Moreover, no limitations from the specification are intended to be read into any claims, unless those limitations are expressly included in the claims. Accordingly, other embodiments are within the scope of the following claims.

What is claimed is:

1. A method of semiconductor processing, comprising:
forming a pattern of features into the surface of a semiconductor substrate; and
growing one or more layers of semiconductor materials over the substrate, wherein one or more of the layers have different crystal lattice dimensions, chemical composition or stoichiometry than the semiconductor substrate.

2. The method of claim 1, wherein the forming comprises;
scribing patterns of lines by mechanical ruling.

3. The method of claim 1, wherein the forming is selected from the group consisting of laser marking, lithography, etching, mechanical scribing, scratching or ruling, or selected growth.

4. The method of claim 1, wherein the growing is selected from the group consisting of atomic layer epitaxy (ALE), atomic layer deposition (ALD), molecular beam epitaxy (MBE), chemical beam epitaxy (CBD), chemical beam epitaxy deposition (CBD), sputtering, magnetron sputtering, plasma reaction deposition, thermal evaporation, electron-beam evaporation, electro-plating, liquid phase epitaxy (LPE), molecular beam epitaxy (MBE) (e.g., metal-organic), chemical vapor deposition (CVD), solid phase epitaxy (SPE) and related combinations of these processes.

5. The method of claim 1, wherein the pattern of features comprises a grid of lines.

6. The method of claim 1, wherein the pattern of features is random.

7. The method of claim 1, wherein the feature dimension is related to the difference between the lattice dimensions of the substrate and the lattice dimensions of the one or more layers.

8. A method of semiconductor processing, comprising:
growing one or more layers of semiconductor materials on a substrate, wherein one or more of the layers has a different chemical composition or stoichiometry than the semiconductor substrate; and
directing a focused laser beam on the substrate to initiate structural and/or electrical property changes at a selected depth corresponding to the focal point of the laser beam.

9. The method of claim 8, wherein the growing is selected from the group consisting of atomic layer epitaxy (ALE), atomic layer deposition (ALD), molecular beam epitaxy (MBE), chemical beam epitaxy (CBD), chemical beam epitaxy deposition (CBD), sputtering, magnetron sputtering, plasma reaction deposition, thermal evaporation, electron-beam evaporation, electro-plating, liquid phase epitaxy (LPE), molecular beam epitaxy (MBE) (e.g., metal-organic), chemical vapor deposition (CVD), and solid phase epitaxy (SPE) and related combinations of these processes.

10. The method of claim 8, wherein the directing comprises scanning the laser beam in a selected pattern over the substrate.

11. A method of semiconductor processing, comprising:
forming a pattern of features on the surface of a semiconductor substrate;
growing one or more layers of semiconductor materials, wherein one or more of the layers has a different chemical composition or stoichiometry than the semiconductor substrate; and
providing a focused laser beam to initiate structural and/or electrical property changes at a selected depth corresponding to the focal point of the laser beam.

12. The method of claim 1, wherein the forming comprises;
scribing patterns of lines by mechanical ruling.

13. The method of claim 11, wherein the forming may be selected from the group consisting of laser marking, lithography, etching, mechanical scribing, scratching or ruling, or selected growth.

14. atomic layer epitaxy (ALE), atomic layer deposition (ALD), molecular beam epitaxy (MBE), chemical beam epitaxy (CBD), chemical beam epitaxy deposition (CBD), sputtering, magnetron sputtering, plasma reaction deposition, thermal evaporation, electron-beam evaporation, electro-plating, liquid phase epitaxy (LPE), molecular beam epitaxy (MBE) (e.g., metal-organic), chemical vapor deposition (CVD), and solid phase epitaxy (SPE) and related combinations of these processes.

15. The method of claim 11, wherein the providing comprises scanning the laser beam in a selected pattern over the substrate.

16. The method of claim 11, wherein the providing the focused laser beam may during the growing or after the growing of the one or more layers of semiconductor material.

17. The method of claim 11, wherein the pattern of features comprises a grid of lines.

18. The method of claim 11, wherein the pattern of features is random.

19. The method of claim 11, wherein the feature dimension is related to the difference between the lattice dimensions of the substrate and the lattice dimensions of the one or more layers.

20. A semiconductor structure, comprising:
a semiconductor substrate having a pattern of features formed into a top surface of the substrate;
a transition layer formed over the substrate; and
an epitaxial layer formed over the transition layer, wherein the lattice dimensions, chemical composition or stoichiometry of the substrate is different than that of the epitaxial layer.

21. The structure of claim 20, wherein the lattice dimensions, chemical composition or stoichiometry of the transition layer may be intermediate between that of the substrate and the epitaxial layer.

22. The structure of claim 20, wherein the pattern of features comprises a grid of lines.

23. The structure of claim 20, wherein the pattern of features is random.

24. The structure of claim 20, wherein the transition layer is formed directly on the substrate.

25. The structure of claim 20, wherein the epitaxial layer is formed directly on the transition layer.
